(19) United States
(12) Patent Application Publication
(10) Pub. No.: US 2011/0037479 A1
(43) Pub. Date: Feb. 17, 2011

(54) Method for Fault Monitoring at a Lighting Output of a Motor Vehicle

(75) Inventor: Ame Rodemer, Frankfurt (DE)

Correspondence Address: COHEN, PONTANI, LIEBERMAN & PAVANE LLP, 551 FIFTH AVENUE, SUITE 1210, NEW YORK, NY, 10176, US

(73) Assignee: Continental Automotive GmbH, Hannover (DE)

(21) Appl. No.: 12/989,270

(22) PCT Filed: Apr. 16, 2009
(86) PCT No.: PCT/EP2009/054489

§ 371 Date: Oct. 22, 2010

(30) Foreign Application Priority Data
Apr. 24, 2008 (DE) 10 2008 020 667.9

(51) Int. Cl. G01R 31/00

(52) U.S. Cl. 324/503

(57) ABSTRACT

A method for fault monitoring at a lighting output of a motor vehicle. Reference current values are first measured and calculated at various reference voltages. During operation of the lighting output, operating current values and operating voltages are measured. If the operating current value at the measured operating voltage deviates from the reference current value at the corresponding reference voltage, then a fault message is output. The method is suitable for detecting a fault even for unknown lamps at the lighting output.

### PRIORITY CLAIM

This is a U.S. national stage of Application No. PCT/EP2009/054489, filed on Apr. 16, 2009,which claims priority to German Application No: 10 2008 020 667.9, filed: Apr. 24, 2008, the contents of which are incorporated herein by reference.

### BACKGROUND OF THE INVENTION

1. Field of the Invention

The invention relates to a method for fault monitoring at a lighting output of a motor vehicle, in which an operating current strength is measured at the lighting output, and a fault message is output if the measured operating current strength deviates from a setpoint value.

2. Related Art

In motor vehicles, an exterior lighting system, which is connected to various lighting outputs, is monitored electronically for faults. The monitoring of the faults extends to the detection of a short circuit or of the failure of a lamp. In the case of known loads connected to the lighting outputs, the monitoring can be carried out easily by simply measuring the current strength.

However, in the case of trailers which are connected to the motor vehicle it is not generally known which lamps, and how many lamps, are connected and whether, if appropriate, even a mixed installation of light emitting diodes and incandescent lamps is present. Consideration could be given to carrying out a simple reference measurement of the current strength at the start of the operation of the lighting output and to using this measurement as a setpoint value for a fault message. If a lamp fails during operation of the lighting output, the subsequent measured current strength deviates from the current strength which results from the reference measurement. However, in this method it is disadvantageous that the measured current strength of a lighting system fluctuates with the operating voltage. Since the operating voltage is also subject to fluctuations during operation of the motor vehicle, this method can lead to fault messages even though all the lamps which are connected to the lighting output are functioning. On the other hand, a fault message may fail to occur if one of a plurality of lamps fails when the operating voltage is rising.

### SUMMARY OF THE INVENTION

An embodiment of the invention is based on of developing a method for fault monitoring such that even in the case of unknown lamps at the lighting output, reliable determination of a failure of a lamp is made possible.

According to one embodiment of the invention a plurality of different reference voltages are applied in succession to the lighting output, and respective reference current values that occur at the different reference voltages are measured. Fault messages output after a comparison of the measured operating current strength at a current operating voltage with the reference current strength as a setpoint value provided for the corresponding reference voltage.

As a result of this configuration, a current/voltage characteristic curve is obtained, that provides definitive information about the profile of the operating current strength of the connected lamps at different operating voltages. It is therefore irrelevant what type of lamp is used, whether there is mixed installation of incandescent lamps and light emitting diodes, and how many lamps are connected to a lighting output. The method according to one embodiment of the invention permits particularly reliable determination of the failure of a lamp. Due to the invention, it is not necessary to detect the type or the number of the lamps connected to the respective lighting output. As a result, the method according to the invention is suitable even in the case of lighting outputs of motor vehicles for trailers in which the type and number of the lamps is unknown.

The setting of different operating voltages for determining the current/voltage characteristic curve is preferably carried out by a pulse-width modulation since a pulse-width modulation unit is available on any controller. In this way, the current/voltage characteristic curve can be determined without additional expenditure on hardware, and the costs for the hardware can be kept particularly low.

The expenditure which is necessary for the method according to the invention can be kept particularly low if the reference voltages applied to the lighting output are lower than the operating voltage after the motor vehicle starts. Since the voltage in the on-board electrical system in a motor vehicle which has started, and in which the dynamo is therefore active, is usually at the upper end of the possible operating voltage range, the selection of the reference voltages below the operating voltage after the motor vehicle starts permits virtually the entire operating voltage range to be covered with measured values.

When ambient conditions change, the voltage of the on-board electrical system in the motor vehicle generally changes. According to another embodiment of the invention, the changed ambient conditions can be simply taken into account in the outputting of the fault message if the reference voltages which are higher than the operating voltage after the motor vehicle starts are determined by extrapolation.

After the lighting output has been activated, there is, in the case of incandescent lamps, at first a warming up time in which the incandescent lamps are firstly heated up. In this warming up time a high current strength flows and drops to a constant value after approximately 100 ms. However, the warming up time is not significant in the case of light emitting diodes. According to another embodiment of the invention, falsification of the reference values by the warming up process is avoided if after the activation of the lighting output begins, the application of the reference voltages is begun after an interval of at least 100 ms. As a result of this configuration it is possible, even in the case of mixed equipment of the lighting output with incandescent lamps and light emitting diodes, to assume that the warming up time has passed and the current drain at the lighting output is virtually constant.

According to another embodiment of the invention, the reference current strengths can be measured with sufficient accuracy over the shortest possible time if the measuring period at the different reference voltages is at least 10 ms.

According to another embodiment of the invention, outputting of incorrect fault messages in the event of fluctuations of the operating current strength as a result of measuring errors and the like can be easily avoided if a tolerance threshold is defined within which a fluctuation of the operating current strength about the reference current strength during the outputting of the fault message is not taken into account.

In the case of travel direction indicators of motor vehicles, it can generally be assumed that the same type of light is arranged on both sides. The method according to the invention can be configured particularly easily with such travel direction indicators if when there are two lighting outputs of a travel direction indicator of the motor vehicle reference voltages are applied to just one of the lighting outputs.

### BRIEF DESCRIPTION OF DRAWINGS

The invention permits numerous embodiments. For the purpose of further clarification of its basic principle, one embodiment thereof is illustrated in the drawing and will be described below. In the drawings:

FIG. 1 is a schematic view of a device for fault monitoring at a lighting output;

FIG. 2 is a graph of the driving of the lighting output with different voltages during a reference measurement; and

FIG. 3 is a graph of current strengths determined at the different voltages of the reference measurement.

### DETAILED DESCRIPTION OF THE DRAWINGS

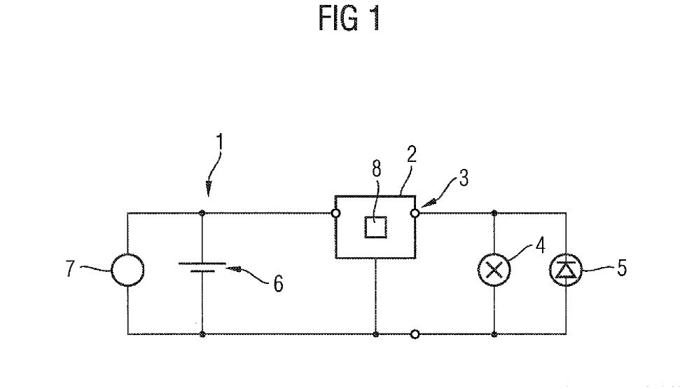

FIG. 1 is a schematic view of a device 2 which is arranged in an on-board electrical system 1 of a motor vehicle and has the purpose of carrying out a method for monitoring a lighting output 3. Two lamps are connected to the lighting output 3, one of which lamps 4, 5 is embodied as an incandescent lamp 4 and the other as a light emitting diode 5. The device 2, and therefore the lighting output 3, are supplied with electric current by a battery 6 and a dynamo 7. Furthermore, the device 2 has a signal generator 8 for outputting the fault message visually and/or acoustically.

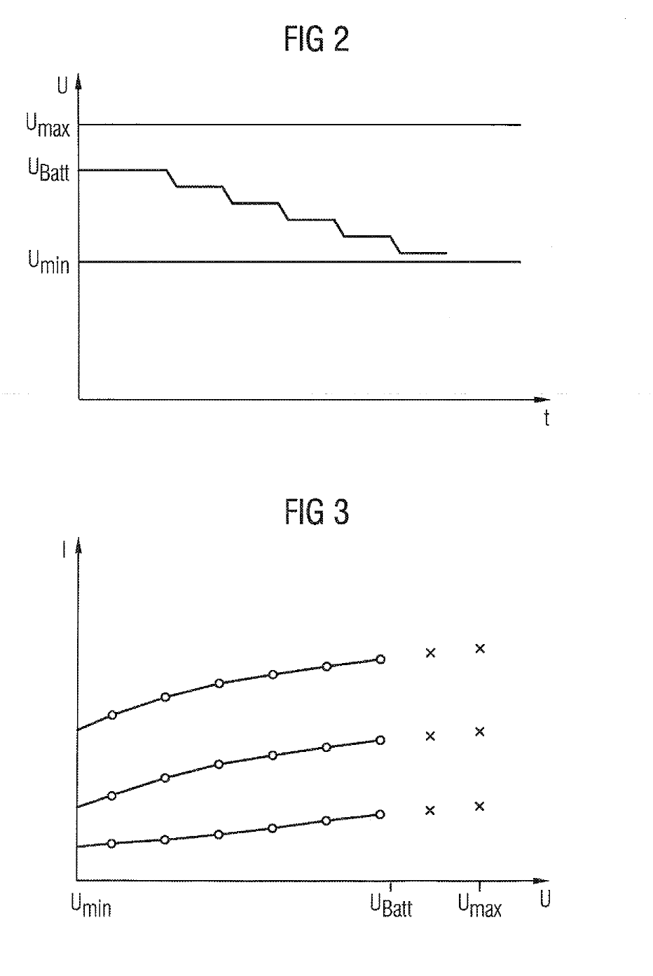

The method for monitoring the lighting output is carried out in that, in a first step, the lighting output 3 is actuated by a connection to the on-board electrical system 1. In a second step, the system subsequently waits for a time period until a constant current strength I has become established. The current strength I is usually constant after approximately 100 ms when, for example, the incandescent lamp has heated up. After a constant current strength I has become established, in a third step various reference voltages U are applied to the lighting output 3. In this context, the voltage U which is applied to the lighting output 3 is reduced incrementally from an output voltage Ubatt to a minimum voltage Umin. This incremental reduction of the voltage U is illustrated in FIG. 2. The reference current strength I which flows at these reference voltages U are measured in a further method step, as is illustrated in FIG. 3. In this respect, FIG. 3 illustrates three curves, the lower curve of which shows the profile of the reference current strength I plotted against the reference voltage U when only light emitting diodes are connected. The central curve symbolizes the profile of the reference current strength I when only incandescent lamps are connected. In the case of the mixed installation of light emitting diodes and incandescent lamps at the lighting output 3, as illustrated in FIG. 1, the top curve is obtained. After the measurements of the reference current strengths I between the voltages Ubatt and Umin have ended, further reference current strengths I between Ubatt and Umax are calculated by extrapolation of the measured values in a subsequent method step. These calculated reference current strengths I are indicated in FIG. 3 by individual points.

The detection of the reference current strengths I is then terminated. These reference current strengths I are used as setpoint values for the lighting output 3 during the subsequent operation of the motor vehicle and of the lighting output.

Then the lighting output 3 is connected to the on-board electrical system 1 and the operating current strengths which occur during operation of the motor vehicle and the operating voltages are determined. When a tolerance threshold for the deviation of the operating current strength from the reference current strength at the respective voltages is exceeded, the signal generator 8 is activated as a last method step, and the driver of the motor vehicle is therefore informed electrically and/or acoustically that a lamp 4, 5 has failed.

The lamps 4, 5 may have completely different characteristics, the current/voltage characteristic curves illustrated in FIG. 3 being just one example thereof. Alternatively, the lamps can also take up a constant current strength over the entire operating voltage range, or even take up a lower current strength when the voltage increases. Likewise, arrangements of light emitting diodes are known in which a number of light emitting diodes are deactivated when the operating voltage drops, which results in jumps in the current/voltage characteristic curve.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-7. (canceled)

8. A method for fault monitoring at a lighting output of a motor vehicle, comprising:
applying, in succession, a plurality of different reference voltages to the lighting output;
measuring respective reference current values that occur at each of the plural different reference voltages;
determining a current setpoint for each of the plural different reference voltages;
measuring an operating current at an operating voltage;
comparing the measured operating current with the current setpoint; and
outputting a fault if the measured operating current deviates from the current setpoint.

9. The method for fault monitoring as claimed in claim 8, wherein the plural different reference voltages are less than an operating voltage after the motor vehicle starts.

10. The method for fault monitoring as claimed in claim 9, wherein the plural different reference voltages that are greater than the operating voltage after the motor vehicle starts are determined by extrapolation.

11. The method for fault monitoring as claimed in claim 8, wherein, the application of the plural reference voltages begins at least 100 ms after an activation of the lighting output.

12. The method for fault monitoring as claimed in claim 8, wherein a measuring period of the plural different reference voltages is at least 10 ms.

13. The method for fault monitoring as claimed in claim 8, further comprising:
defining a tolerance threshold within which a fluctuation of the operating current about the reference current for which the outputting of the fault message is ignored.

14. The method for fault monitoring as claimed in claim 8, wherein when there are two lighting outputs of a travel direction indicator of the motor vehicle reference voltages are applied to just one of the lighting outputs.

15. The method for fault monitoring as claimed in claim 8, wherein the plural different reference voltages that are greater than an operating voltage after the motor vehicle starts are determined by extrapolation.

16. The method for fault monitoring as claimed in claim 10, wherein, the application of the plural reference voltages begins at least 100 ms after an activation of the lighting output.

17. The method for fault monitoring as claimed in claim 16, wherein a measuring period of the plural different reference voltages is at least 10 ms.

18. The method for fault monitoring as claimed in claim 17, further comprising:
defining a tolerance threshold within which a fluctuation of the operating current about the reference current for which the outputting of the fault message is ignored.
